(19) United States
(12) Patent Application Publication
(10) Pub. No.: US 2008/0292813 A1
(43) Pub. Date: Nov. 27, 2008

(54) Microwave Heating Device With Irradiation Arrangement

(75) Inventors: José M. Catala-Civera, Valencia (ES); Frank Morgenweck, Zur Russeer (DE); Domingo Rohde, Kiel (DE)

Correspondence Address: EASTMAN KODAK COMPANY;PATENT LEGAL STAFF, 343 STATE STREET, ROCHESTER, NY, 14650-2201, US

(73) Assignee: EASTMAN KODAK COMPANY, Rochester, NY (US)

(21) Appl. No.: 11/658,436

(22) PCT Filed: Jul. 11, 2005
(86) PCT No.: PCT/EP05/07474

§ 371 Date: Feb. 7, 2008

(30) Foreign Application Priority Data
Jul. 29, 2004 (DE) 10 2004 036 826.0

(51) Int. Cl. C23C 14/28; C23C 14/56

(52) U.S. Cl. 427/595; 118/46

(57) ABSTRACT

The invention relates to a heating device (1) for heating at least one printing agent provided on a printing material (10), said heating device comprising at least one microwave applicator (5) for bombarding the printing material (10) with microwave radiation, and comprising at least one irradiation arrangement (8) for irradiating and melt-depositing the printing agent by means of electromagnetic radiation; as well as to an appropriate method for heating at least one printing agent. A heating device (1) and a method are to be provided which allow a design that is less complex overall. In accordance with the present invention this object is achieved, considering the apparatus, in that the radiation arrangement (8), as well as the printing material (10) and the printing agent, are bombarded by the microwave radiation of the microwave applicator (5), so that the irradiation arrangement (8) is excited to emit electromagnetic radiation.

The present invention relates to a heating device for heating at least one printing agent provided on a printing material, said heating device comprising at least one microwave applicator for bombarding the printing material with microwave radiation, and comprising at least one irradiation arrangement for irradiating and melt-depositing the printing agent by means of electromagnetic radiation. Furthermore, the invention relates to a method for heating at least one printing agent provided on the printing material by bombardment with microwave radiation and by irradiation with a radiation source, while heating takes place with microwave radiation.

In virtually any printing process, solid or liquid printing agents such as dyes, inks, lacquers or toners are applied to a printing material. During the continuation of the printing process, either liquid printing agents or parts thereof must be evaporated, or the solid printing agents or parts thereof must be fused to the printing material.

This evaporation or fusing may occur by contacting methods, for example, via heating rollers, or by non-contacting methods. In conjunction therewith, arrangements are known which use infrared radiation, UV radiation or microwave radiation, or also combinations of these types of radiation. In so doing, infrared radiation and UV radiation heat the printing agent due to spectral absorption, while the printing material is essentially heated by microwave radiation. Then, heating of the printing agent occurs essentially indirectly via the heated printing material. To achieve this, the printing material must be sufficiently heated. When combinations of different types of radiation are used, advantageously the microwave radiation intensity can be selected in such a manner, for example, that the heated printing material does not release enough thermal energy to the printing agent in order to permit melt-deposition or evaporation. Only a combination with another type of radiation, such as UV radiation, achieves appropriate heating of the printing agent.

For example, toner is used as the printing agent in an electrophotographic printing process. First, a latent charge image is developed by charged toner particles. This toner image is then transferred to a printing material. This printing material may, for example, be paper, cardboard, film or the like. In order to generate a stable printed image, the toner particles must be firmly applied to the printing material. This requires a fusing device. This fusing device fuses melt-deposits the toner, thus fusing it to the printing material.

There are contacting and non-contacting fusing processes; for example, in a contacting fusing process, pressure and heat are applied to the toner in such a manner that it is fused to the printing material. To achieve this, the printing material with the toner is passed between two hot rollers, for example.

Furthermore, various other non-contacting fusing processes are known. In this case, for example, the toner is fused to the printing material by UV radiation or by microwave radiation. It has also been known to combine various fusing processes; for example, the toner may be fused to a printing material by simultaneous bombardment with microwave radiation and UV radiation.

The device suggested by DE 100 64 561 provides that a radiation lamp, in this case a gas-discharge lamp, which emits radiation in the ultraviolet region of the spectrum, hereinafter briefly referred to as UV lamp, be arranged outside the microwave field. In so doing, the UV lamp is uncoupled from the microwave arrangement in such a manner that no microwave radiation acts on said lamp but that UV radiation radiates into the microwave arrangement. The problem with this device is the limited useful life of a conventional UV lamp due to the erosion of electrodes and due to the switching times required before the UV radiation becomes effective. Furthermore, the separation of the zones, in which the microwave radiation is effective, from the zone of the UV lamp is a problem because any separation always requires shielding and thus restricts the effectiveness of the radiation arrangement; less UV radiation reaches the surface of the printing material than is emitted by the radiation source. To achieve this separation, DE 100 64 561 provides a screen, which separates the zones from each other and has a mesh size such that all or most of the MW radiation is reflected by the screen.

The described complexity of the apparatus for separating the irradiation arrangement zone from the zone, in which microwave radiation is applied to the printing agent or the printing material, is not only considerable and cost-intensive but also susceptible to breakdown on account of this complexity.

The object of the present invention is to provide a heating device and a method of the aforementioned types, which permit a design that is simpler overall.

In accordance with the present invention, this object is achieved, considering the apparatus, in that the irradiation arrangement, as well as the printing material and the printing agent, are bombarded by the microwave radiation of the microwave applicator.

Accordingly, the method provides that the microwave radiation acts simultaneously on the printing agent and on the printing material, as well as on the irradiation arrangement, so that the irradiation arrangement is excited to emit electromagnetic radiation.

To achieve this, the irradiation arrangement can advantageously be excited pre-dominantly by the microwave radiation, which is already used in the heating process, in order to emit electromagnetic radiation. This emitted electromagnetic radiation can be used at least to aid the heating process. Furthermore, any hard to maintain separation of the application zone of the microwave radiation and the radiation arrangement zone is no longer necessary in this case. Without separation, the emitted electromagnetic radiation of the radiation arrangement is not shielded, hence the arrangement's effectiveness is increased.

This advantageous embodiment provides that the irradiation arrangement be designed in such a manner that an excitation of the irradiation arrangement by the microwave radiation is desirable. In the irradiation arrangement, the microwave radiation generates—with an extremely short latency period—an emission of electromagnetic radiation. The electromagnetic radiation emitted by the irradiation arrangement should have its spectrum essentially in the wavelength range between 1 nm and 10 μm.

Depending on the thickness or density of the printing agent on the printing material and/or the type of printing agent used, different intensities of radiation to be emitted by the irradiation arrangement may be required. These intensities correlate with the fields strengths of the microwave radiation acting on the irradiation arrangement; therefore, it is advantageous if the intensity of the electromagnetic radiation of the irradiation arrangement is changed as a function of the printing agent density on the printing material and of the properties of the printing material. Advantageously, this is achieved in that the field strength of the microwave radiation acting on the irradiation arrangement is varied. Considering the apparatus, at least one setting element for setting the field strength of the microwave radiation, which is to act on the irradiation arrangement, is provided. As a result of this, it is advantageously possible to adjust the field strength in the zone of the irradiation arrangement. Furthermore, it is possible, in accordance with the invention, to vary the intensity of the microwave radiation radiated into the microwave applicator.

In particular, the irradiation arrangement and the microwave application zone may be separated by a separating panel, and the zone of the irradiation arrangement is supplied with microwave radiation, independent of the application zone. The origin of the microwave radiation may then be located in the same microwave source as is used for the microwave radiation of the microwave application zone. To achieve this, the microwave radiation may be divided by a potentially variable power divider.

In accordance with the method herein, it may also be advantageous to shift the irradiation arrangement within the microwave applicator. Said irradiation arrangement can then be shifted into zones where the required field strength exists. This is made possible by an inhomogeneous field inside the microwave applicator.

One embodiment provides that the minimum of one setting element is a microwave tuning element for adapting the electrical field strength in the microwave applicator in the zone of the irradiation arrangement.

Such a microwave tuning element may be an element of metal, silica glass or PTFE, for example.

A particularly favorable embodiment provides that the microwave tuning element is a pivotable pin which extends into the field zone of the microwave applicator. By pivoting or moving the pin into the field zone, different field strengths can easily be achieved in the zone of the irradiation arrangement. For example, this pin may consist of one of the aforementioned materials.

In accordance with the invention, the setting element may be a separating panel which is partially permeable at least to the electromagnetic radiation of the irradiation arrangement or to the electromagnetic radiation of the irradiation arrangement and the microwave radiation—for separating a microwave application zone from an irradiation arrangement zone. For example, this separating panel may be a wire mesh or a metal sheet with holes.

A particularly advantageous embodiment provides an appropriate, at least partially permeable screen as the separating panel. For example, this screen may have a mesh size which is large enough for the required microwave radiation to enter the zone of the irradiation arrangement to allow the appropriate amount of radiation of the irradiation arrangement to enter the microwave application zone in order to bombard the toner on a printing material in that zone. As a result of this, an easy control of the microwave radiation acting on the irradiation zone is achieved, while, at the same time, the effectiveness of the irradiation arrangement is high. The mesh size of such a screen allows more electromagnetic radiation of the irradiation arrangement to pass than would be the case if the entry of microwave radiation had to be prevented. Consequently, the effectiveness of the irradiation arrangement has been improved favorably.

The requirements of the emitted radiation of the irradiation source may be variable; therefore, it is favorable if the setting element is an adjustable coupling element in the at least partially permeable separating panel, said coupling element coupling the microwave application zone with the irradiation arrangement zone in such a manner that at least part of the microwave radiation is transmitted into the zone of the irradiation arrangement. The field strength in the zone of the irradiation arrangement can be changed by adjusting the coupling element.

In accordance with the invention, the coupling element may be a diaphragm or an electrical conductor. The aperture size of the diaphragm may be changed in order to vary the microwaves to be transmitted, while the pin can be slid in or out of the microwave applicator zone and thus more or less microwave energy is transmitted.

Heating of the printing agent on the printing material can be aided by microwave radiation; therefore, the radiation emitted by the irradiation arrangement is essentially within the ultraviolet region of the spectrum.

Furthermore, a printing agent is used which can be cross-linked by the electromagnetic radiation of the irradiation arrangement. By doing so, a cross-linking of the printing agent on the surface of the printing material is achieved, which, advantageously allows for a more stable printed image, which cannot be blurred easily or be otherwise impaired negatively. Specifically in duplex printing, this chemical change of the printing agent prevents already cross-linked printing agents on the surface of a printing material from being melted again or from being otherwise impaired in the heating device.

An inventive modification provides that the used irradiation arrangement be a gas-discharge lamp. The selection of such a lamp permits an easy change of the spectral region emitted by the irradiation arrangement, namely by changing the gas. The emitted radiation, for example, can then be adapted to different types of printing agents by using a second gas-discharge lamp or a second gas. Therefore, the invention further provides that gas-discharge lamps with different gas compositions be used.

Advantageously, the method provides that gas-discharge lamps using different gas densities be used. Depending on the density, more or less microwave radiation is absorbed by the irradiation arrangement and, then, electromagnetic radiation with increased or decreased intensity is emitted as result of the excitation of the gas. In this manner, the intensity of the radiation emitted by the irradiation arrangement can be adapted to the density or thickness or type of the printing agent.

Another embodiment provides that the gas-discharge lamp be excited by means of electrodes aiding the emission of electromagnetic radiation. It has been found that an already excited gas-discharge lamp absorbs more microwave radiation than a not excited gas-discharge lamp. As a result of this, the intensity of the emitted radiation of the irradiation source can be increased and adapted to the density, thickness or type of printing agent on the printing material.

An alternative embodiment provides that the irradiation arrangement be configured as an electrodeless gas-discharge lamp. The excitation of the gas of the gas-discharge lamp then takes place by itself via the microwave radiation of the microwave applicator. As a result of this, advantageously, an electrode erosion, which would shorten the useful life of conventional gas-discharge lamps, can be avoided.

The preferred use of the heating device in an electrophotographic printing machine further provides that the printing agent, advantageously, is a toner. The heating device may then act as a fusing device which fuses the toner to the printing material.

Embodiments of the inventive heating device, which could result in additional inventive features, which, however, do not restrict the present invention, are illustrated in the drawings which show in

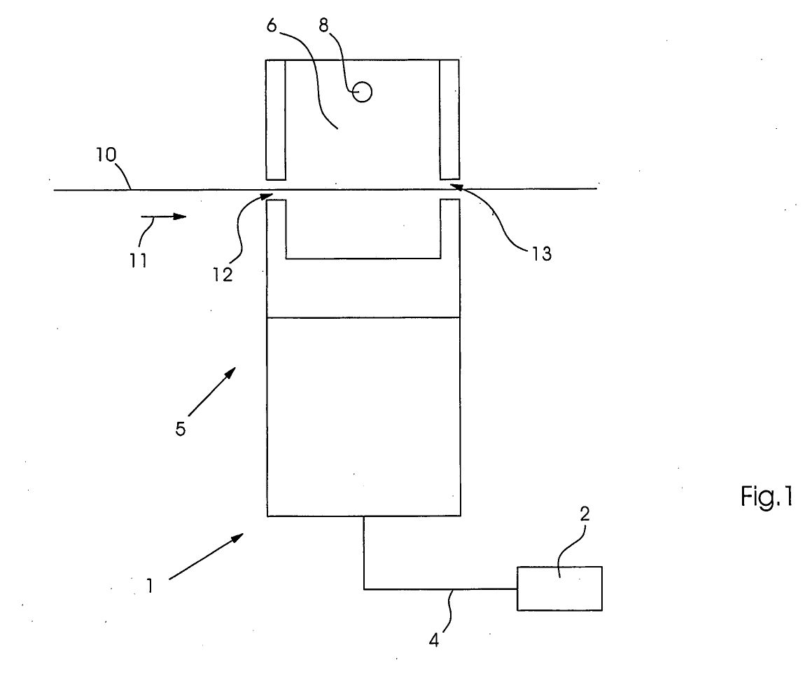

FIG. 1 a side elevation of a diagram of the heating device;

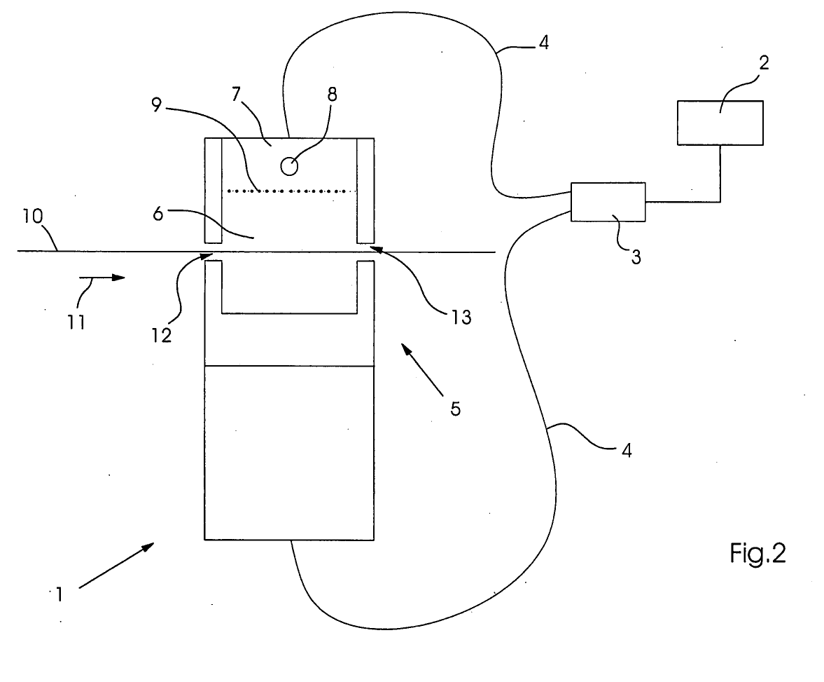

FIG. 2 a side elevation of a heating device with a power divider;

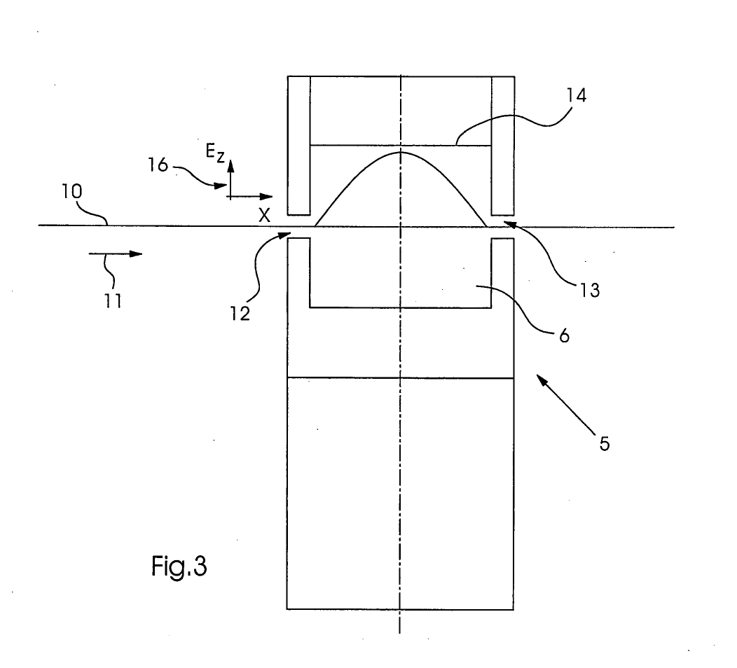

FIG. 3 a schematic illustration of the microwave field strength progression inside a microwave applicator;

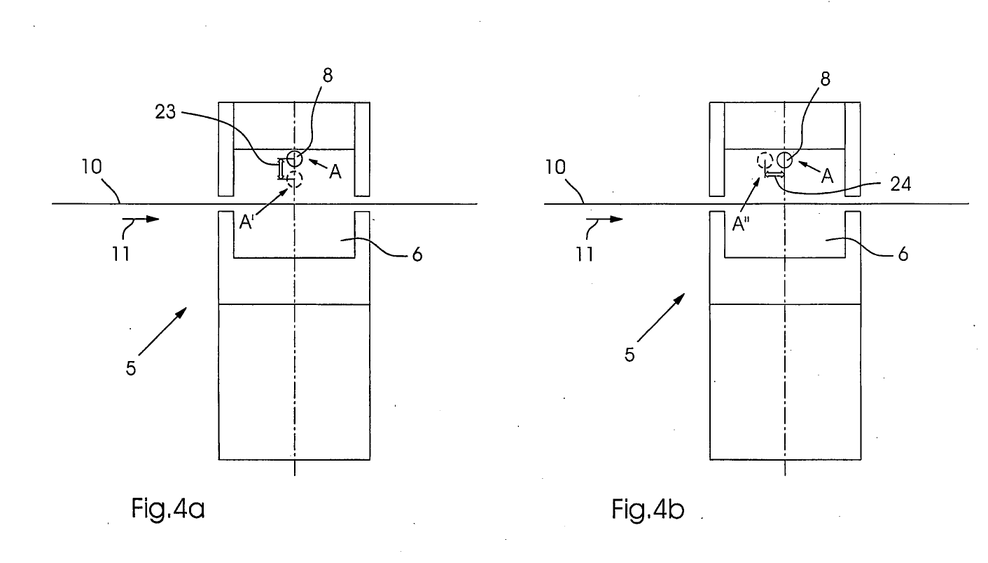

FIG. 4a a schematic illustration of a microwave applicator with an adjustable irradiation arrangement;

FIG. 4b a schematic illustration of a microwave applicator with an alternative, adjustable irradiation arrangement;

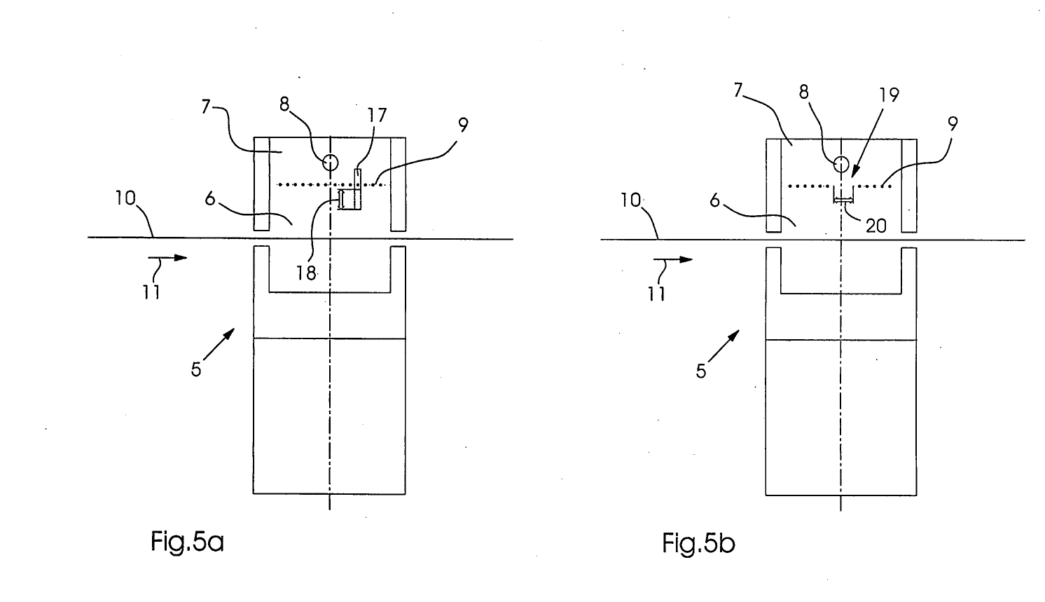

FIG. 5a a microwave applicator with an electrical conductor as the coupling element;

FIG. 5b a microwave applicator with a diaphragm as the coupling element;

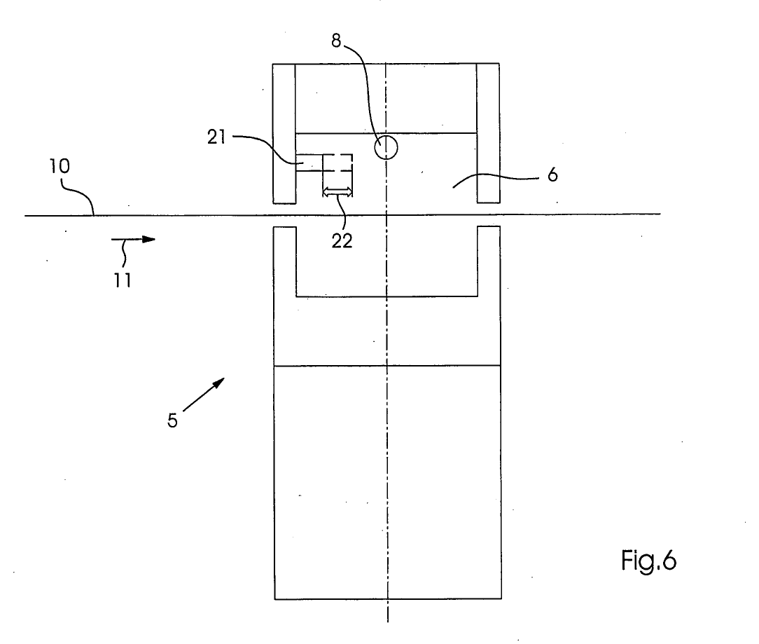

FIG. 6 a microwave applicator with a pivotable pin as the microwave tuning element.

FIG. 1 shows a schematic side elevation of a fusing device 1 as the heating device. In so doing, fusing device 1 comprises a microwave source 2, which guides microwave radiation through a microwave input line 4 to a microwave applicator 5. Microwave applicator 5, in turn, comprises a microwave application zone 6, in which, in the case shown here, an irradiation arrangement configured as a gas-discharge lamp 8 is provided.

A printing material 10 is transported through microwave applicator 5. In so doing, printing material 10 is transported and guided by transport and guiding elements not illustrated here. Printing material 10, for example, may be a sheet of paper. Printing material 10 moves along a transport path 11 indicated by an arrow. Printing material 10 can be guided through microwave applicator 5, in that said printing material is guided through slits 12 and 13.

FIG. 2 shows a side elevation of a schematic illustration of a fusing device 1. In this case, fusing device 1 comprises, in addition to the aforementioned elements of FIG. 1, a power divider 3 and an additional microwave input line 4, which guide microwave radiation from different directions into different zones of microwave applicator 5. In particular, power divider 3 may be variable and/or feed microwave radiation of different intensities into the different zones of microwave applicator 5.

Microwave applicator 5 has a microwave application zone 6 and a zone 7 of gas-discharge lamp 8. Microwave application zone 6 and zone 7 of gas-discharge lamp 8 are separated from each other by a separating panel 9. In the case shown here, separating panel 9 consists of a screen or of a metal sheet with holes, said screen being at least partially permeable to electromagnetic radiation emitted by gas-discharge lamp 8 and being essentially impermeable to the microwave radiation of microwave application zone 6. The radiation emitted by gas-discharge lamp 8 may be types of radiation having different spectral compositions. In the cases shown here, however, this radiation preferably is electromagnetic radiation in the ultraviolet region of the spectrum.

In the case shown here, microwave radiation is guided through microwave input lines 4, on the one hand, into microwave application zone 6 and, on the other hand, into zone 7 of gas-discharge lamp 8. In so doing, it is specifically possible to supply microwave application zone 6 and zone 7 with microwaves in such a manner that said MW waves exhibit different microwave field strength distributions. As already described, also in this case printing material 10 is passed through slits 12 and 13 through microwave applicator 5.

FIG. 3 shows the distribution of the electrical field strength of the microwave radiation in microwave application zone 6 of microwave applicator 5. Graph 15 shows the progression of the microwave field strength. A coordinate system 16 is attached for easier understanding of the curve of the field strength as a function of the longitudinal direction (from the x-direction) inside microwave applicator zone 6. Also in this case, a printing material 10 is depicted, which is passed in the direction of transport path 11 through microwave application zone 6.

FIGS. 4a and 4b represent alternative possibilities for moving a gas-discharge lamp 8 inside microwave application zone 6. In this case, it is also possible to separate gas-discharge lamp 8 by a separating panel 9 from microwave application zone 6 and to place said lamp in zone 7. FIG. 4a shows a shift of gas-discharge lamp 8 in a direction perpendicular to the plane of printing material 10. The irradiation arrangement is moved from its original position A along a shift 23 into a second position A′. This movement is indicated here by a bolded arrow. FIG. 4b shows a shift 24 of gas-discharge lamp 8 parallel to the plane of printing material 10. In this case, gas-discharge lamp 8 is moved along a shift 24—illustrated by an arrow—out of the original position A to a third position A′. Combinations of shifts 23, 24, as shown in FIG. 4a and FIG. 4b, are also possible. The same reference numbers as in previous figures are used for the same elements in FIGS. 4a and 4b.

By using shifts 23, 24 of gas-discharge lamp 8 to a second position A′ or a third position A″, gas-discharge lamp 8 arrives in positions of an electromagnetic field strength different from FIG. 3.

FIGS. 5a and 5b show alternative coupling elements. FIG. 5a shows a lateral view of a microwave applicator 5 with an electrical conductor 17 as the coupling element. Again, the same reference numbers describe the same elements. Here, electrical conductor 17 can be moved in and out of microwave application zone 6 along a shift 18. Electrical conductor 17 is enclosed by separating panel 9 in an essentially non-contacting manner. This non-contacting enclosure can be ensured, for example, in that conductor 17 is a coaxial cable.

FIG. 5b shows a diaphragm 19 as the coupling element between a microwave application zone 6 and a zone 7 of gas-discharge lamp 8 of microwave applicator 5. In this case, the size of diaphragm 19 can be enlarged by one shift 20. In so doing, more or less microwave radiation may pass from microwave application zone 6 into zone 7 of gas-discharge lamp 8.

FIG. 6 is a lateral view of microwave applicator 5 with a microwave tuning element. The same reference numbers refer to the same elements as in previous figures.

The microwave tuning element in this case, for example, is a pin 21 which can be pivoted by a shift 22 into and out of microwave application zone 6 of the microwave applicator. In the case shown here, gas-discharge lamp 8 is located in microwave application zone 6. However, the invention also provides that gas-discharge lamp 8 is separated from microwave application zone 6 by means of a separating panel 9. In this case microwave application zone 6, as well as zone 7, may contain both microwave tuning elements which are configured, for example, as pins 21; however, different microwave tuning elements are conceivable in zones 6 and 7. Here again, the same numbers refer to the same elements as in the previous drawings.

The heating device shown in FIGS. 1 through 6 is a fusing device 1; however, it may just as well be a heating device for drying ink or lacquers by means of microwave radiation. For example, printing material 10 may be paper to which a not-illustrated toner image has been applied. In this case, the toner image is a layer on the printing material located in front of microwave applicator 5. Inside microwave applicator 5, the toner particles are fused to the printing material by means of microwave radiation and UV radiation emitted by gas-discharge lamp 8. In so doing, gas-discharge lamp 8 absorbs the microwave radiation of microwave applicator 5 for the purpose of excitation.

As shown by FIG. 1, the non-fused toner image on printing material 10 is moved on printing material 10 along transport path 11 through microwave applicator 5. Then, inside microwave applicator 5, printing material 10 and the toner image are bombarded by microwave radiation and UV radiation of gas-discharge lamp 8. To achieve this, the gas of gas-discharge lamp 8 is excited by means of the microwave radiation of microwave applicator 5 to emit radiation. Gas-discharge lamp 8 is located in microwave application zone 6 of microwave applicator 5.

Due to the simultaneous bombardment of the printing material with microwave radiation and UV radiation, the toner is fused to printing material 10. In so doing, advantageously, the UV radiation acts directly on the toner. The microwave radiation, which is present in microwave applicator 5 anyhow, is used for the excitation of gas-discharge lamp 8. A complex separation of microwave application zone 6 and zone 7 of gas-discharge lamp 8 is not necessary in this case.

As shown by FIG. 2, it is also possible to provide gas-discharge lamp 8 in a zone 7 and to separate it by a separating panel 9 from microwave application zone 6. Microwave application zone 6 and zone 7 may be separately supplied with microwave radiation via microwave input lines 4. In the case illustrated here, separating panel 9, for example, may consist of a screen having a mesh size which is suitable to prevent microwave radiation from penetrating. In this case, zones 6 and 7 of microwave applicator 5 are not coupled for passage of microwave radiation. Therefore, it is possible, by means of power divider 3, to generate different microwave strengths in microwave application zone 6 and in zone 7. As a result of this—adjusted to the type of printing material 10 and to the density of the toner or another printing agent on the surface of printing material 10—preferred intensities of microwave radiation and of the UV radiation emitted by gas-discharge lamp 8 can be set. This allows the optimal enhancement of a fusing process by means of fusing device 1.

FIGS. 4a and 4b show that gas-discharge lamp 8 can be moved along a vertical or a horizontal shift 23, 23 inside microwave application zone 6. As can be seen in FIG. 3, gas-discharge lamp 8, depending on the position A, A′ or A″ to which said lamp is moved, is bombarded with a microwave field strength of varying intensity. Depending on the intensity of the microwave radiation used for bombardment, the gas of gas-discharge lamp 8 is excited to emit electromagnetic radiation of varying intensity. In so doing, positions A, A′ or Au of gas-discharge lamp 8 inside the microwave application zone should be selected in such a manner that they optimally enhance the fusion of a toner to printing material 10. The intensity of the emitted electromagnetic radiation that is to be generated is adapted to the thickness or density of the toner on printing material 10. To achieve this, gas-discharge lamp 8 can be moved to positions A, A′, A″, said positions displaying a microwave field strength of the desired intensity.

FIGS. 5a and 5b essentially show the same fusing devices 1 as shown in the previous figures. In this case, a not illustrated toner on a printing material 10 inside microwave applicator 5 is bombarded with microwave radiation and UV radiation of a gas-discharge lamp 8 in such a manner that the toner is fused to printing material 10. In the cases illustrated here, gas-discharge lamp 8 is provided in a zone 7, which is separated by separating panel 9 from microwave application zone 6. Specifically, separating panel 9 may be a screen that is partially permeable to microwave radiation and UV radiation. In this case, the mesh size should be selected in such a manner that the microwave radiation can pass through the openings of the screen in the respectively adjoining zone. In order to adapt the UV radiation emitted by gas-discharge lamp 8 to the actual toner densities or toner thicknesses on the printing material 10, setting elements 17 and 19 are provided in separating panel 9. Setting element 17 is an electrical conductor which can be moved into and out of microwave application zone 6 along shift 8. Depending on the length with which electrical conductor 17 extends into microwave application zone 6, more or less microwave radiation traverses from microwave application zone 6 into zone 7 of gas-discharge lamp 8. This allows a control of the field strength of the microwave radiation acting on the gas of gas-discharge lamp 8. Depending on the field strength of the microwave radiation, different intensities of UV radiation are emitted by gas-discharge lamp 8, said radiation acting on the toner of printing material 10. As described, this intensity should be adjusted to the toner density or toner thickness.

FIG. 5b shows a diaphragm 19, the aperture of which can be enlarged or made smaller by a shift 20. Depending on the aperture size, diaphragm 19 allows more or less microwave radiation into zone 7 of gas-discharge lamp 8. As described, this allows a control of the UV radiation emitted by gas-discharge lamp 8 through the aperture of diaphragm 19.

FIG. 6 shows another adjustment option for control of the microwave radiation acting on gas-discharge lamp 8. In this case, gas-discharge lamp 8 again is located directly in microwave application zone 6 of microwave applicator 5. With the use of a pivotable pin 21, the intensity of the microwave radiation acting on gas-discharge lamp 8 can be influenced. Pin 21 can be pivoted along a shift 22 in microwave application zone 6. Depending on shift 22, this pin then causes the microwave field in microwave application zone 6 to be decreased or increased. For example, pin 21 may consist of silica glass, PTFE or even of metal. However, it is also possible, though not shown here, for pin 21 to be located in a zone 7 of gas-discharge lamp 8, which is separated by separating panel 9 from microwave application zone 6. To achieve this, separating panel 9 may be configured as a screen, which is at least partially permeable to microwave radiation. In addition to the mesh size of the screen, pin 21 can affect the field strength of the microwave radiation in zone 7. Thus a control of the intensity of UV radiation emitted by gas-discharge lamp 8 becomes possible.

In each of the cases mentioned here it is possible to bias gas-discharge lamp 8. The intensity of the emitted UV radiation can be additionally affected by this bias. Depending on the bias, more or less UV radiation is emitted. Also, biasing can favorably improve the absorption behavior of gas-discharge lamp 8 as regards microwave radiation. Consequently, the resultant degree of effectiveness of fusing device 1 is improved.

In all of the described cases, it is also possible to use electrodeless gas-discharge lamps 8; advantageously avoids electrode erosion, thus increasing the useful life of the gas-discharge lamp.

Each case of the cases illustrated here provides that a toner or another printing agent be applied to printing material 10, said toner or printing agent being subjected to cross-linking due to the action of UV radiation. In this manner, due to the effect of the microwave radiation in microwave applicator 5, the toner is fused to the surface of printing material 10, and, due to the effect of UV radiation from the gas-discharge lamp said toner is additionally cross-linked on the surface of said printing material. Consequently, due to this chemical cross-linking reaction, a particularly stable printed image is formed on the surface of printing material 10, whereby said printed image is less subject to damage in the course of subsequent printing processes.

1. Heating device for heating at least one printing agent provided on a printing material (10), said heating device comprising at least one microwave applicator (5) for bombarding the printing material (10) with microwave radiation, and comprising at least one irradiation arrangement for bombarding and fusing the printing agent by means of electromagnetic radiation,
characterized in that
the irradiation arrangement, as well as the printing material (10) and the printing agent are bombarded by microwave radiation of the microwave applicator (5).

2. Heating device as in claim 1,
characterized in that
at least one of the setting elements for setting the field strength of the microwave radiation, with which the irradiation arrangement is bombarded, is provided.

3. Heating device as in claim 2,
characterized in that
the setting element is a microwave tuning element for adapting the electrical field strength in the microwave applicator in the zone of the irradiation arrangement.

4. Heating device as in claim 3,
characterized in that
the microwave tuning element is a pivotable pin (21) which extends into the field zone of the microwave applicator.

5. Heating device as in claim 2,
characterized in that
the setting element is at least one separating panel (9), which is at least partially permeable to the electromagnetic radiation of the irradiation arrangement or to the electromagnetic radiation and the microwave radiation, in order to separate a microwave applications zone (6) from a zone (7) of the irradiation arrangement.

6. Heating device as in claim 5,
characterized in that
the separating panel (9) consists of a screen which is at least partially permeable to the electromagnetic radiation of the irradiation arrangement or the electromagnetic radiation of the irradiation arrangement and the microwave radiation.

7. Heating device as in at least one of the claims 2, 5 and 6,
characterized in that
the setting element is an adjustable coupling element in the at least partially permeable separating panel, which said coupling element couples the microwave application zone and the zone of the irradiation arrangement in such a manner that at least part of the microwave radiation is transmitted into the zone of the irradiation arrangement.

8. Heating device as in claim 4,
characterized in that
the coupling element is a diaphragm (19).

9. Heating device as in claim 4,
characterized in that
the coupling element is an electrical conductor (17).

10. Heating device as in at least one of the claims 1 through 9,
characterized in that
the emitted electromagnetic spectrum of the irradiation arrangement is essentially radiation in the ultraviolet region of the spectrum.

11. Heating device as in at least one of the claims 1 through 10,
characterized in that
a printing agent is used which can be cross-linked by the electromagnetic radiation of the irradiation arrangement.

12. Heating device as in at least one of the claims 1 through 11,
characterized in that
the used irradiation arrangement is a gas-discharge lamp (8).

13. Heating device as in claim 12,
characterized in that
the gas-discharge lamp (8) is electrodeless.

14. Heating device as in one of the claims 1 through 13,
characterized in that
the printing agent is a toner.

15. Method for heating at least one printing agent on a printing material (1) by bombardment with microwave radiation and by irradiation of the microwave radiation by means of an irradiation arrangement, while heating occurs,
characterized in that
the microwave radiation acts on the printing agent and the printing material, as well as on the irradiation arrangement, in such a manner that said irradiation arrangement is excited to emit electromagnetic radiation.

16. Method as in claim 15
characterized in that
the field strength of the microwave radiation acting on the irradiation arrangement is varied.

17. Method as in claim 16
characterized in that
the irradiation arrangement is shifted inside the microwave applicator (5).

18. Method as in claim 16
characterized in that
setting elements are used to set the field strength in the zone of the irradiation arrangement.

19. Method as in claim 15
characterized in that
the intensity of the electromagnetic radiation emitted by the irradiation arrangement is changed as a function of the printing agent density on the printing material (10).

20. Method as in claim 15
characterized in that
a gas-discharge lamp (8) is used as the irradiation arrangement.

21. Method as in claims 19 and 20
characterized in that
gas-discharge lamps (8) having different gas compositions are used.

22. Method as in claims 19 and 20
characterized in that
gas-discharge lamps (8) having different gas densities are used.

23. Method as in claims 19 and 20
characterized in that
the gas-discharge lamp (8) is excited by electrodes aiding the emission of electromagnetic radiation.

24. Method as in at least one of the claims 15 through 22
characterized in that
an electrodeless gas-discharge lamp (8) is used as the irradiation arrangement.

25. Method as in at least one of the claims 15 through 24
characterized in that
the printing agent is cross-linked on the printing material by the electromagnetic radiation emitted by the irradiation arrangement.

26. Method as in at least one of the claims 15 through 25
characterized in that
toner is used as the printing agent.
